(19) United States
(12) Patent Application Publication
(10) Pub. No.: US 2023/0290690 A1
(43) Pub. Date: Sep. 14, 2023

(54) TSV TEST STRUCTURE AND TSV SHORT TEST METHOD

(71) Applicant: CHANGXIN MEMORY TECHNOLOGIES, INC., Hefei City (CN)

(72) Inventor: Jiarui Zhang, Hefei City (CN)

(73) Assignee: CHANGXIN MEMORY TECHNOLOGIES, INC., Hefei City (CN)

(21) Appl. No.: 18/168,085

(22) Filed: Feb. 13, 2023

Related U.S. Application Data
(63) Continuation of application No. PCT/CN2022/099939, filed on Jun. 20, 2022.

(30) Foreign Application Priority Data
Mar. 14, 2022 (CN) 202210247673.1

(51) Int. Cl. H01L 21/66; H01L 21/768

(52) U.S. Cl. CPC H01L 22/14; H01L 21/76898

(57) ABSTRACT

A TSV test structure includes: a plurality of TSV groups, each TSV group comprising electrically connected TSVs; a power supply circuit, connected with the TSV groups and configured to provide a first voltage or a second voltage to each TSV group; a control circuit, connected to the power supply circuit and configured to provide a first control signal and a second control signal to the power supply circuit, wherein the power supply circuit outputs the first voltage to at least one TSV group according to the first control signal, and outputs the second voltage to at least one TSV group according to the second control signal; and a readout circuit, electrically connected with the plurality of TSV groups and configured to read electrical signals on the plurality of TSV groups after the control circuit provides the first control signal and the second control signal.

### CROSS-REFERENCE TO RELATED APPLICATIONS

This application is a continuation of International Application No. PCT/CN2022/099939, filed on Jun. 20, 2022, which claims priority to Chinese Patent Application No. 202210247673.1, filed on Mar. 14, 2022. The disclosures of the above-referenced applications are hereby incorporated by reference in their entirety.

### TECHNICAL FIELD

The present disclosure relates to the technical field of integrated circuits, and in particular to a Through Silicon Via (TSV) test structure and a TSV short test method.

### BACKGROUND

The Through Silicon Via (TSV) technology is a new technical solution for realizing interconnection of stacked chips in three-dimensional integrated circuits. The TSV can make the stacking density of chips in three dimensions the highest, the interconnection wires among the chips the shortest, and the overall dimensions the smallest, and greatly improve the chip speed and reduce the power consumption, so it has become one of the most existing remarkable electronic packaging technologies. As a signal transmission channel among multiple dies, the reliability of TSV directly affects the yield of the whole chip. Therefore, TSV test is an important part of integrated circuit test.

It is to be noted that some of the information disclosed in the above background is used only to enhance understanding of the context of the present disclosure, and thus may include information not constituting the related art known to those of ordinary skill in the art.

### SUMMARY

The present disclosure relates to the technical field of integrated circuits, and provides a TSV test structure and a TSV short test method for overcoming, at least to a certain extent, the problem of being unable to test a TSV short circuit due to the limitations and defects of the related art.

According to the first aspect of the present disclosure, a TSV test structure is provided, which may include: a plurality of TSV groups, a power supply circuit, a control circuit, and a readout circuit. Each TSV group includes a plurality of electrically connected TSVs. The power supply circuit is connected with the plurality of TSV groups and used for providing a first voltage or a second voltage to each TSV group. The first voltage is different from the second voltage. The control circuit is connected to the power supply circuit and provides a first control signal and a second control signal to the power supply circuit. The power supply circuit outputs the first voltage to at least one TSV group according to the first control signal, and outputs the second voltage to at least one TSV group according to the second control signal. The readout circuit is electrically connected with the plurality of TSV groups, and is configured to read electrical signals on the plurality of TSV groups after the control circuit provides the first control signal and the second control signal.

According to the second aspect of the present disclosure, a TSV short test method is provided, which may include the following operations. A first TSV group and at least one second TSV group adjacent to the first TSV group are determined from a plurality of TSV groups. A first voltage is provided to the first TSV group, and a second voltage is provided to the at least one second TSV group. Electrical signals on the first TSV group and the at least one second TSV group are read sequentially. It is determined whether there is a short circuit between the first TSV group and the at least one second TSV group according to the electrical signals.

By providing the first voltage and the second voltage different from the first voltage to adjacent TSV groups and performing readout detection on the TSV groups, the embodiments of the present disclosure can quickly and effectively detect the TSV group with a short circuit, and even detect the TSV group with an open circuit.

It is to be understood that the above general descriptions and detailed descriptions below are only exemplary and explanatory and not intended to limit the present disclosure.

### BRIEF DESCRIPTION OF THE DRAWINGS

The accompanying drawings, which are incorporated in and constitute a part of this specification, illustrate embodiments consistent with the present disclosure and, together with the description, serve to explain the principles of the present disclosure. It is apparent that the accompanying drawings described below are merely some embodiments of the disclosure, and other drawings can be obtained by those of ordinary skill in the art according to these accompanying drawings without creative efforts.

FIG. 1 is a structure diagram of a TSV test structure in an exemplary embodiment of the present disclosure.

FIG. 2 is a schematic diagram of a power supply circuit in an embodiment of the present disclosure.

FIG. 3 is a schematic diagram of a power supply subcircuit in an embodiment of the present disclosure.

FIG. 4A is a schematic diagram of a readout circuit in an embodiment of the present disclosure.

FIG. 4B is a schematic diagram of a readout circuit in an embodiment of the present disclosure.

FIG. 5 is a flowchart of a TSV short test method in an exemplary embodiment of the present disclosure.

FIG. 6A is a top view of TSV groups in an embodiment of the present disclosure.

FIG. 6B is a top view of TSV groups in an embodiment of the present disclosure.

FIG. 7 is a principle diagram of short detection of TSV groups in an embodiment of the present disclosure.

FIG. 8 is a flowchart of the operation in S54 in an embodiment of the present disclosure.

FIG. 9 is a connection relation diagram of a readout circuit in another embodiment of the present disclosure.

### DETAILED DESCRIPTION

Exemplary implementation modes will now be described more comprehensively with reference to the accompanying drawings. However, the exemplary implementation modes can be implemented in many forms and should not be understood to be limited to the examples described here; on the contrary, these implementation modes makes the present disclosure more comprehensive and complete, and fully communicates the concept of the exemplary implementation modes to those skilled in the art. The described characteristics, structures, or features can be combined in one or more implementation modes in any proper way. In the following descriptions, many specific details are provided to give a full understanding of the implementation modes of the present disclosure. However, those skilled in the art will appreciate that the technical solution of the present disclosure may be performed while omitting one or more of the specific details, or other methods, components, apparatuses, steps, etc. may be employed. In other cases, the well-known technical solutions are not shown or described in detail, so as to avoid obscuring various aspects of the present disclosure.

In addition, the accompanying drawings are merely schematic illustrations of the present disclosure. The same reference signs in the drawings denote the same or similar parts, so repeated description thereof will be omitted. Some block diagrams shown in the drawings are functional entities and do not necessarily correspond to physically or logically separate entities. These functional entities may be implemented in software, or these functional entities may be implemented in one or more hardware modules or integrated circuits, or these functional entities are implemented in different networks and/or processor apparatuses and/or micro-controller apparatuses.

The exemplary implementation modes of the present disclosure are elaborated below in combination with the accompanying drawings.

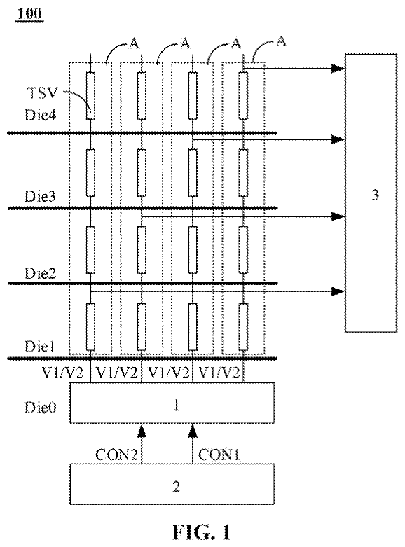

FIG. 1 is a structure diagram of a TSV test structure in an exemplary embodiment of the present disclosure.

Referring to FIG. 1, a TSV test structure 100 may include: a plurality of TSV groups A and a power supply circuit 1 connected to the plurality of TSV groups A, a control circuit 2, and a readout circuit 3.

The power supply circuit 1 is used for providing a first voltage V1 or a second voltage V2 to each TSV group A. The first voltage V1 is different from the second voltage V2.

The control circuit 2 is connected to the power supply circuit 1 and provides a first control signal CON1 and a second control signal CON2 to the power supply circuit 1, to enable the power supply circuit 1 to output the first voltage V1 to at least one TSV group A according to the first control signal CON1, and output the second voltage V2 to at least one TSV group A according to the second control signal CON2.

The readout circuit 3 is electrically connected with the plurality of TSV groups A, and is configured to read electrical signals on the plurality of TSV groups A after the control circuit 2 provides the first control signal CON1 and the second control signal CON2.

In the embodiment shown in FIG. 1, the TSV group A includes a plurality of electrically connected TSVs, the TSVs are arranged respectively in a plurality of chip layers (Diel to Die4), and the control circuit 2 is arranged in the outermost chip layer (Die0). The TSVs in each TSV group A are aligned, and the plurality of chip layers are vertically bonded through the plurality of TSV groups A to form a highly integrated stacked package. In other embodiments of the present disclosure, stacking forms achieved by the TSV groups A may also be, for example, wafer to wafer, chip to wafer, or chip to chip, and bonding modes may include, for example, direct Cu—Cu bonding, bonding, direct fusion, welding, etc., which is not specially limited by the present disclosure.

The TSV group A may be used for transmitting signals between chips in different layers. Depending on the starting position of the signal, the number of TSVs in each TSV group A is not exactly the same. FIG. 1 only shows an example. In practical applications, the numbers of TSVs in different TSV group A may be one or more than one.

The power supply circuit 1 and the readout circuit 3 may be electrically connected to the TSV group A by being directly connected to the TSV located on the outermost side of the stacked chip or by being connected to any conductive part of each TSV group A through leads that are preset and made.

The diameter of the TSV is usually 1 um to 50 um, the depth is usually 10 um to 150 um, and the aspect ratio is 3 to 5 or even higher. There are usually about hundreds or even thousands of TSVs in a chip, that is, there are usually hundreds or even thousands of TSV groups after packaging. In the process of drilling, filling and bonding of the TSVs, there are occasionally some process defects, such as residue of abrasive slurry, particle contamination, copper particles, stress caused by cracking, and edge fragments, which may lead to a short circuit between adjacent TSVs.

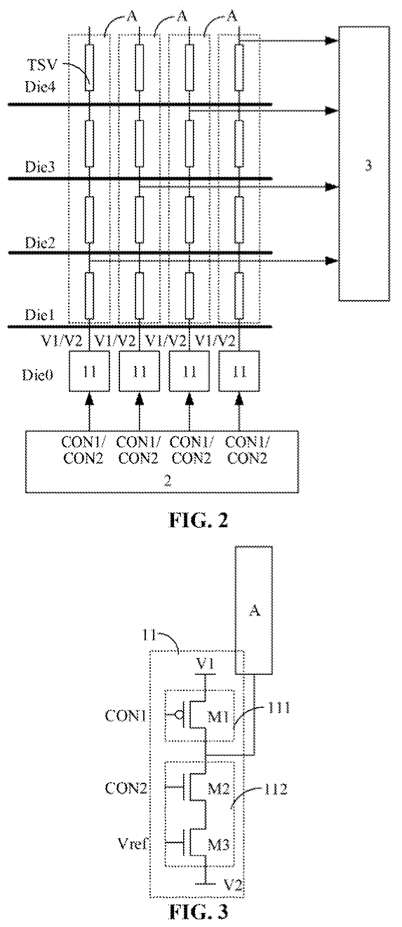

FIG. 2 is a schematic diagram of a power supply circuit in an embodiment of the present disclosure.

Referring to FIG. 2, in an exemplary embodiment of the present disclosure, the power supply circuit 1 includes a plurality of power supply subcircuits 11. Each of the power supply subcircuits 11 is correspondingly connected to one of the TSV groups A, and the power supply subcircuit 11 is configured to provide the first voltage V1 or the second voltage V2 to the TSV group A. Correspondingly, the control circuit 2 provides the first control signal CON1 or the second control signal CON2 to each power supply subcircuit 11, the first control signal CON1 is configured to control the power supply subcircuit 11 to output the first voltage V1, and the second control signal CON2 is configured to control the power supply subcircuit 11 to output the second voltage V2.

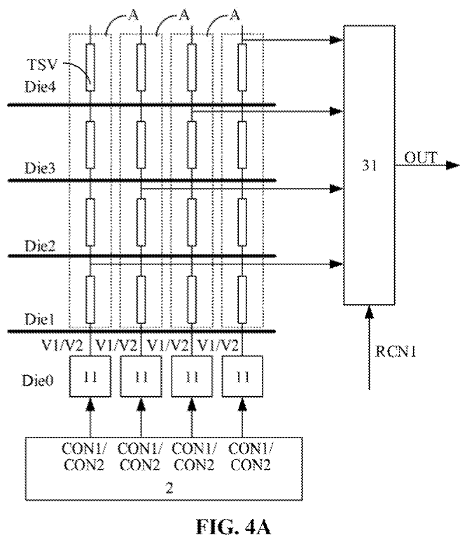

FIG. 3 is a schematic diagram of a power supply subcircuit in an embodiment of the present disclosure.

Referring to FIG. 3, in an embodiment of the present disclosure, the power supply subcircuit 11 includes a pull-up module 111 and a pull-down module 112. The pull-up module 111 is configured to output the first voltage V1 according to the first control signal CON1, and the pull-down module 112 is configured to output the second voltage V2 according to the second control signal CON2.

In the embodiment shown in FIG. 3, the pull-up module 111 includes a first transistor M1. The first electrode of the first transistor M1 receives the first voltage V1, the gate of the first transistor M1 receives the first control signal CON1, and the second electrode of the first transistor M1 is connected to a TSV group A. The pull-down module 112 includes a second transistor M2 and a third transistor M3. The first electrode of the second transistor M2 is connected to the TSV group A, the second electrode of the second transistor M2 is connected to the first electrode of the third transistor M3, and the gate of the second transistor M2 receives the second control signal CON2. The second electrode of the third transistor M3 receives the second voltage V2, and the gate of the third transistor M3 receives a bias voltage Vref.

In an exemplary embodiment of the present disclosure, the first voltage V1 is greater than the second voltage V2, and the second voltage V2 is less than or equal to the zero potential. In the embodiment shown in FIG. 3, for example, the first voltage V1 is a power voltage Vcc, and the second voltage V2 is GND. In other embodiments, the second voltage V2 may also be a negative voltage as long as it can be clearly distinguished from the first voltage V1.

The bias voltage Vref may be used for controlling the rate at which the power supply subcircuit 11 outputs the second voltage V2 and improving the pull-down capability of the pull-down module 112.

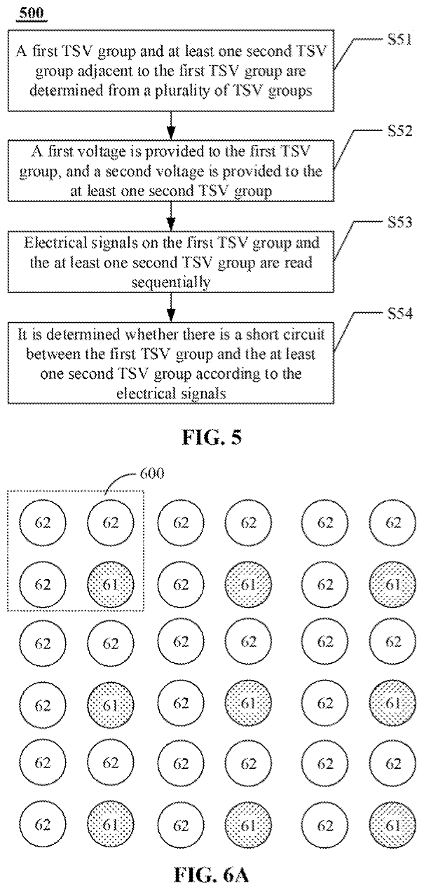

Through the circuit of the embodiment shown in FIG. 3, each TSV group A may be set to the first voltage V1 or the second voltage V2, thus forming a variety of voltage distribution patterns, and the short circuit between the TSV groups is measured in a variety of scenarios. The detailed method may refer to the following embodiment shown in FIG. 5.

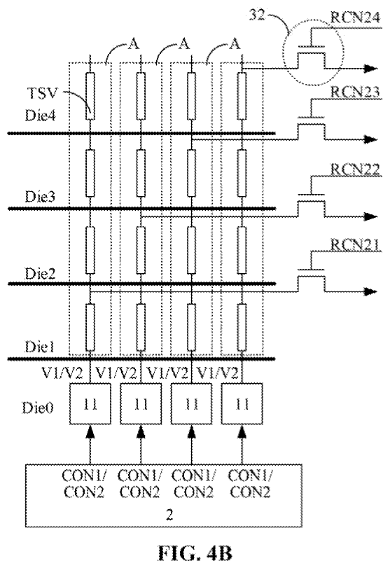

FIG. 4A and FIG. 4B are schematic diagrams of a readout circuit in an embodiment of the present disclosure.

Referring to FIG. 4A, in an embodiment of the present disclosure, the readout circuit 3 includes a shift register 31. Each of input ends of the shift register 31 are connected to one TSV group A, and a control end of the shift register 31 is connected to a first read control signal RCN1. The first read control signal RCN1 is used for controlling the shift register to sequentially read the electrical signals on the TSV groups. The first read control signal RCN1 may be from the control circuit 2.

Referring to FIG. 4B, in another embodiment of the present disclosure, the readout circuit 3 includes a plurality of switch units 32. The first end of each switch unit 32 is connected to one TSV group A, the second end outputs the electrical signals on the TSV group A, and the control end is connected to a second read control signal RCN2i (i=1, 2, 3 . . . ); a plurality of the second read control signals RCN2i sequentially turn on the plurality of switch units 32 and read out the electrical signals on the TSV groups A. The second read control signal RCN2i may be from the control circuit 2.

The control circuit 2 may execute the TSV short test method provided in the embodiments of the present disclosure, control a voltage state of each TSV group A, obtain read data on the TSV group A, and determine whether there is a short circuit among multiple TSV groups A.

FIG. 5 is a flowchart of a TSV short test method in an exemplary embodiment of the present disclosure.

Referring to FIG. 5, the method 500 may include the following operations.

At S51, a first TSV group and at least one second TSV group adjacent to the first TSV group are determined from a plurality of TSV groups.

At S52, a first voltage is provided to the first TSV group, and a second voltage is provided to the at least one second TSV group.

At S53, electrical signals on the first TSV group and the at least one second TSV group are read sequentially.

At S54, it is determined whether there is a short circuit between the first TSV group and the at least one second TSV group according to the electrical signals.

In an embodiment, the operation in S51 may include the following operations. The plurality of TSV groups are divided into a plurality of test groups, each test group includes at least two adjacent TSV groups, and the number of TSV groups in each test group is not exactly the same. A TSV group in each test group is set as the first TSV group, and other TSV groups in the test group are set as the second TSV groups. Each of the second TSV groups is adjacent to the first TSV group.

In this case, the operation in S52 may include the following operations. The first voltage is provided to the first TSV group in each of the plurality of test groups, and the second voltage is provided to each of the second TSV groups in the test group. The operation in S53 may include the following operations. The electrical signals on the first TSV group and the second TSV group in each test group are read. Test data corresponding to each test group is determined according to the logic level of each electrical signal.

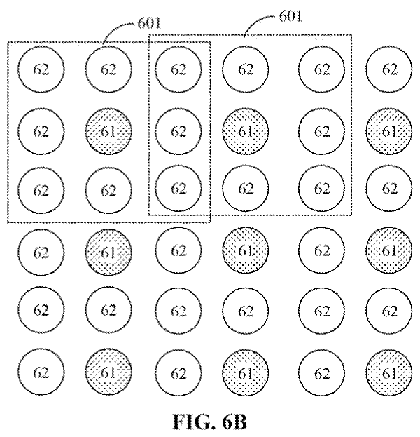

FIG. 6A and FIG. 6B are top views of TSV groups in an embodiment of the present disclosure.

In the embodiments shown in FIG. 6A and FIG. 6B, the TSV groups A are arranged in array on the top view of the view angle parallel to the chip.

Referring to FIG. 6A, in an embodiment, four TSV groups form a test group 600; each test group 600 has one first TSV group 61 and three second TSV groups 62, and the second TSV groups 62 are all adjacent to the first TSV group 61. When data of the TSV groups is read, test data groups are formed according to the test groups.

Referring to FIG. 6B, in another embodiment, nine TSV groups form a test group 601; each test group 601 has one first TSV group 61 and eight second TSV groups 62. The second TSV groups 62 are all adjacent to the first TSV group 61, and eight second TSV groups 62 surround the first TSV group 61. When the data of the TSV groups is read, test data groups are formed according to the test groups.

In the embodiments shown in FIG. 6A and FIG. 6B and other embodiments of the present disclosure, different test groups may have the same TSV group, that is, a TSV group may be included in different test groups, so as to more fully measure a short path between every two adjacent TSV groups.

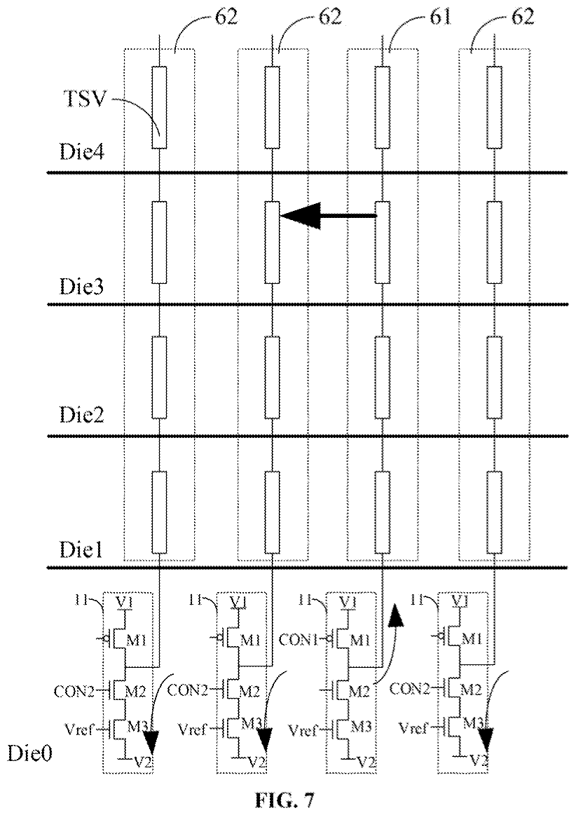

FIG. 7 is a principle diagram of short detection of TSV groups in an embodiment of the present disclosure.

Referring to FIG. 7, taking four TSV groups being a test group in the embodiment shown in FIG. 6A as an example, the first control signal CON1 is input to the power supply subcircuit 11 connected to the first TSV group 61, and the second control signal CON2 is input to the power supply subcircuit 11 connected to the second TSV group 62, so that the first voltage V1 is provided to the first TSV group 61, and the second voltage V2 is provided to the second TSV group 62.

Assuming that there is a short path between the first TSV group 61 and adjacent second TSV group 62 (as shown by the arrow in FIG. 7), and taking the second TSV group 62 on the left of the first TSV group 61 as an example, after the first TSV group 61 is charged to a high voltage (the first voltage) and before reading, the first TSV group 61 conducts with the second TSV group 62 with a low voltage through the short path, resulting in the voltage rise of the second TSV group 62. When read, both the electrical signal of the first TSV group 61 and the electrical signal of the second TSV group 62 on the left of the first TSV group are the electrical signals of logic level 1. Therefore, it may be determined in S54 whether there is a short circuit between the first TSV group 61 and its adjacent second TSV group 62 according to the electrical signals.

In some embodiments, in order to improve the leakage rate between the first TSV group 61 and the second TSV group 62 and enhance the short-circuit effect, the first voltage V1 may be increased, namely “strong 1”. For example, the method for increasing the first voltage V1 is to increase the power voltage by a charge pump, or to connect a pull-up unit of each power supply subcircuit 11 to the higher power voltage, which is not specially limited by the present disclosure. The specific value of the first voltage V1 may be set according to the overall requirements of the integrated circuit, and may be as high as possible under the condition of meeting the safety requirements, so as to make a larger potential difference between the first TSV group 61 and the second TSV group 62, improve the leakage rate between the first TSV group 61 and the second TSV group 62, enhance the short-circuit effect, and improve the detection efficiency.

The embodiments shown in FIG. 6A and FIG. 6B are taken as examples to illustrate the operations in S53 and S54. Under normal conditions, in the read data of a test group, 1 bit should be 1, and other bits should be 0. In the presence of a short circuit, in the read data of a test group, multiple bits may be 1 or all bits may be 0, which is completely different from normal.

Therefore, it is able to determine whether a test group is in a preset normal condition corresponding to the position of the first TSV group by determining the read data of the test group, and then, when the read data of the test group is not equal to the corresponding data of the normal condition, it is determined that there is a short path between the first TSV group 61 and the second TSV group 62 in the test group.

In combination with the embodiment shown in FIG. 6A, the reading sequence may be set as reading the first TSV group 61 and then reading the three second TSV groups 62, then the corresponding data of the test group should be equal to 0001 (binary). If the corresponding final data of the test group is not 0001, it can be determined that there is a short path between the first TSV group 61 and the second TSV group 62 in the test group.

When the reading sequence is the first second TSV group 62, the second second TSV group 62, the first TSV group 61, and the third second TSV group 62, under the normal condition, the read data is 0010. If the read data is wrong data, such as 0011, 1010, or 0110, it can be determined that there is a short path in the test group. Even when the read data is abnormal data, such as 1110 and 0111, it is determined that there is more than one short path in the test group.

By comparing the read data with the preset data, the number and position of the short paths in a test group can be determined more accurately, and then the faulty TSV group can be located.

In another embodiment, a more convenient method may be used to determine whether there is a short path in a test group.

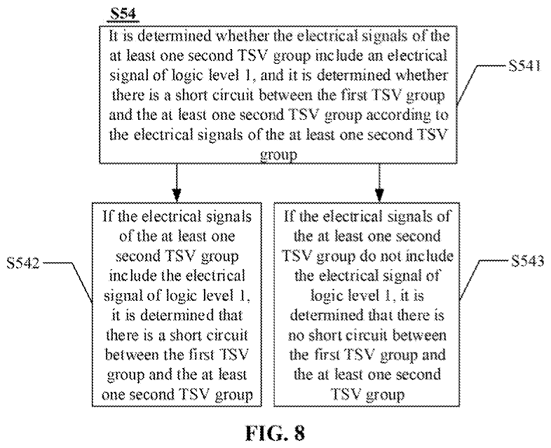

FIG. 8 is a flowchart of the operation in S54 in an embodiment of the present disclosure.

Referring to FIG. 8, in an exemplary embodiment of the present disclosure, the operation in S54 may also include the following operations.

At S541, it is determined whether the electrical signals of the at least one second TSV group include an electrical signal of logic level 1, and it is determined whether there is a short circuit between the first TSV group and the at least one second TSV group according to the electrical signals of the at least one second TSV group.

At S542, if the electrical signals of the at least one second TSV group include the electrical signal of logic level 1, it is determined that there is a short circuit between the first TSV group and the at least one second TSV group.

At S543, if the electrical signals of the at least one second TSV group do not include the electrical signal of logic level 1, it is determined that there is no short circuit between the first TSV group and the at least one second TSV group.

The embodiment shown in FIG. 8 is a specific example of logical judgment. When the first voltage V1 is high, if there is a short circuit between the first TSV group 61 and its adjacent second TSV group 62, the voltage after the short circuit is logic level 1. In such case, by determining whether there is logic level 1 in the second TSV groups 62, whether a short circuit exists can be more accurately determined.

It is determined whether a short circuit exists only by determining whether a second TSV group 62 is in logic level 1, so that the judgment efficiency can be improved. Wherever a short circuit occurs, the data consisting of the electrical signal of each second TSV group 62 necessarily include 1. Compared with determining the read data of the test group and determining whether there is a short circuit according to the specific values of the read data of the whole test group, the method is more convenient and efficient, and there is no need to modify the benchmark data for judgment and the judgment logic because of the different positions of the first TSV group 61 in the test group.

Further, in an exemplary embodiment of the present disclosure, the second TSV group with the electrical signal of logic level 1 may also be determined in S541, so as to determine the position of the second TSV group short-circuited with the first TSV group.

Still taking the test group shown in FIG. 6A as an example, assuming that only the data of the second TSV groups 62 is determined, under normal conditions, the corresponding data of multiple second TSV groups 62 should be equal to 0; if there is a data bit with a value equal to 1, it may be determined which one or several of the second TSV groups 62 have a short circuit with the first TSV group 61 according to the correspondence between the data bit and the second TSV groups 62. Of course, there may be a short circuit between two of multiple second TSV groups 62, and there may a short circuit between one of the two second TSV groups 62, rather than both the two second TSV groups 62, and the first TSV group 61.

To prevent misjudgment, transposition measurements may be performed on a test group in the embodiments of the present disclosure. For example, assuming that a test group includes four TSV groups a, b, c and d, in the first measurement, the TSV group a is set as the first TSV group 61, the TSV groups b, c and d are set as the second TSV group 62, and the first group of data is measured. In the second measurement, the TSV group c, which is at a diagonal with the TSV group a, is set as the first TSV group 61, the TSV groups a, b and d are set as the second TSV groups 62, and the second group of data is measured.

Next, it is determined whether all data bits of the first group of data and the second group of data are equal to 0. If all the data bits of the first group of data and the second group of data are equal to 0, it is indicated that there is no short circuit among the adjacent TSV groups a, b, and d, and the adjacent TSV groups c, b, and d. If the first group of data has one or more data bits that are not equal to 0, it is indicated that there is a short circuit among the TSV groups a, b, and d; if the second group of data has one or more data bits that are not equal to 0, it is indicated that there is a short circuit among the TSV groups c, b, and d. The specific short path may be determined according to the first group of data, the second group of data and the reading sequence of the TSV groups.

The above test strategies are only examples. In practical applications, the test strategies for a test group may be adjusted according to the adjacency of the TSV groups. Those skilled in the art can set the test strategies according to the actual situation. By measuring a test group in a variety of ways, the short path can be accurately and comprehensively located, thus providing technical support for the subsequent repair or alternative solutions.

The testing principle of the embodiment shown in FIG. 6B is the same. The embodiment shown in FIG. 6B can read the data of eight second TSV groups 62 once, which can greatly improve the testing efficiency compared with the embodiment shown in FIG. 6A. However, in the case of multiple tests on a test group, the corresponding test scheme of the embodiment shown in FIG. 6B is more complex.

After the short circuit in a test group is measured, another test group may be tested, or multiple test groups may be tested at the same time to improve the testing efficiency. In some embodiments, different test groups may also share the same TSV group(s) to avoid missing the short circuit among the TSV groups of different test groups.

In addition, although multiple TSV groups in the embodiments of the present disclosure are arranged in array, in other scenarios, the multiple TSV groups may also be arranged irregularly according to the actual conditions of the circuits and chips (for example, the distribution of idle areas), in this case, the division of the test groups may be determined according to the distance between the TSV groups (for example, two TSV groups whose distance is less than a preset value are determined as adjacent TSV groups). The number of TSV groups in each test group may not be necessarily the same, and different test groups may also include the same TSV groups, which is not specially limited by the present disclosure.

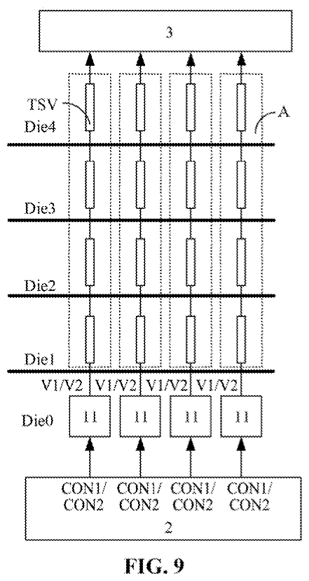

FIG. 9 is a connection relation diagram of a readout circuit in another embodiment of the present disclosure.

Referring to FIG. 9, in some embodiments, if both ends of a TSV group are located on the second edge layer of a stacked chip/wafer, the readout circuit 3 may be connected to the other end, which is not connected to the power supply circuit 1, of the TSV group, and then the readout circuit 3 may determine whether the first voltage V1 is transmitted from one end of the first TSV group to the other end while reading the voltage at the end of the first TSV group, so as to determine whether there is an open circuit in the first TSV group. Finally, the one or more TSV groups having a short circuit are determined in combination with the determination results on the open circuit and short circuit. By setting different TSV groups as the first TSV group in turn, the short and open tests for all TSV groups can be completed.

In the embodiments of the present disclosure, by using a simple circuit to apply the first voltage or the second voltage to the adjacent TSV groups, a voltage difference is made to cause a short circuit, and finally, the short circuit is located according to the read data. Compared with the related art, simpler circuit setting, higher test efficiency and higher test accuracy can be obtained no matter how many layers the chips are stacked.

It is to be noted that, although a plurality of modules or units of the device for action execution are mentioned in the foregoing detailed descriptions, but this division is not mandatory. Actually, according to the implementation modes of the present disclosure, the foregoing described features and functions of two or more modules or units may be embodied in a module or unit. On the contrary, the foregoing described features and functions of a module or unit may further be embodied by a plurality of modules or units.

Other implementations of the present disclosure will be apparent to those skilled in the art from consideration of the specification and practice of the present disclosure. The present disclosure is intended to cover any variations, uses, or adaptations of the present disclosure following the general principles thereof and including such departures from the present disclosure as come within known or customary practice in the art. The specification and embodiments are considered as exemplary only, and the true scope and concept of the present disclosure are indicated by the claims.

By providing the first voltage and the second voltage different from the first voltage to adjacent TSV groups and performing readout detection on the TSV groups, the embodiments of the present disclosure can quickly and effectively detect the TSV group with a short circuit, and even detect the TSV group with an open circuit.

What is claimed is:

1. A Through Silicon Via (TSV) test structure, comprising:
a plurality of TSV groups, each TSV group comprising a plurality of electrically connected TSVs;
a power supply circuit, connected with the plurality of TSV groups and configured to provide a first voltage or a second voltage to each TSV group, wherein the first voltage is different from the second voltage;
a control circuit, connected to the power supply circuit and configured to provide a first control signal and a second control signal to the power supply circuit, wherein the power supply circuit outputs the first voltage to at least one TSV group according to the first control signal, and outputs the second voltage to at least one TSV group according to the second control signal; and
a readout circuit, electrically connected with the plurality of TSV groups and configured to read electrical signals on the plurality of TSV groups after the control circuit provides the first control signal and the second control signal.

2. The TSV test structure of claim 1, wherein the power supply circuit comprises a plurality of power supply subcircuits, each of the power supply subcircuits is connected to a respective one of the TSV groups, and configured to provide the first voltage or the second voltage to the TSV group.

3. The TSV test structure of claim 2, wherein the control circuit provides the first control signal or the second control signal to each of the power supply subcircuits, the first control signal is configured to control the power supply subcircuit to output the first voltage, and the second control signal is configured to control the power supply subcircuit to output the second voltage.

4. The TSV test structure of claim 3, wherein the power supply subcircuit comprises a pull-up module configured to output the first voltage according to the first control signal and a pull-down module configured to output the second voltage according to the second control signal.

5. The TSV test structure of claim 4, wherein the pull-up module comprises a first transistor, a first electrode of the first transistor receives the first voltage, a gate of the first transistor receives the first control signal, and a second electrode of the first transistor is connected to the TSV group; and
the pull-down module comprises a second transistor and a third transistor, a first electrode of the second transistor is connected to the TSV group, a second electrode of the second transistor is connected to a first electrode of the third transistor, and a gate of the second transistor receives the second control signal, a second electrode of the third transistor receives the second voltage, and a gate of the third transistor receives a bias voltage.

6. The TSV test structure of claim 1, wherein the first voltage is greater than the second voltage, and the second voltage is less than or equal to zero potential.

7. The TSV test structure of claim 1, wherein the readout circuit comprises a shift register, each of input ends of the shift register is connected to a respective one of the TSV groups, and a control end of the shift register is connected to a first read control signal used for controlling the shift register to sequentially read the electrical signals on the TSV groups.

8. The TSV test structure of claim 1, wherein the readout circuit comprises a plurality of switch units, a first end of each of the switch units is connected to one of the TSV groups, a second end of the switch unit outputs an electrical signal on the TSV group, and a control end of the switch unit is connected to a second read control signal, and wherein a plurality of the second read control signals sequentially turn on the plurality of switch units and read out the electrical signals on the TSV groups.

9. A Through Silicon Via (TSV) short test method, comprising:
determining a first TSV group and at least one second TSV group adjacent to the first TSV group from a plurality of TSV groups;
providing a first voltage to the first TSV group, and providing a second voltage to the at least one second TSV group;
reading electrical signals on the first TSV group and the at least one second TSV group sequentially; and
determining whether there is a short circuit between the first TSV group and the at least one second TSV group according to the electrical signals.

10. The TSV short test method of claim 9, wherein the first voltage is greater than the second voltage, and the second voltage is less than or equal to zero potential.

11. The TSV short test method of claim 9, wherein determining whether there is the short circuit between the first TSV group and the at least one second TSV group according to the electrical signals comprises:
determining whether the electrical signals of the at least one second TSV group comprise an electrical signal of logic level 1, and determining whether there is the short circuit between the first TSV group and the at least one second TSV group according to the electrical signals of the at least one second TSV group;
responsive to that the electrical signals of the at least one second TSV group comprise the electrical signal of logic level 1, determining that there is the short circuit between the first TSV group and the at least one second TSV group;
responsive to that the electrical signals of the at least one second TSV group comprise no electrical signal of logic level 1, determining that there is no short circuit between the first TSV group and the at least one second TSV group.

12. The TSV short test method of claim 11, wherein determining whether the electrical signals of the at least one second TSV group comprise the electrical signal of logic level 1, and determining whether there is the short circuit between the first TSV group and the at least one second TSV group according to the electrical signals of the at least one second TSV group comprises:
determining a second TSV group with the electrical signal of logic level 1, to determine a position of the second TSV group having a short circuit with the first TSV group.

13. The TSV short test method of claim 9, wherein determining the first TSV group and the at least one second TSV group adjacent to the first TSV group from the plurality of TSV groups comprises:
dividing the plurality of TSV groups into a plurality of test groups, each test group comprising at least two adjacent TSV groups;
setting a TSV group in each test group as the first TSV group, and setting other TSV groups in the test group as the second TSV groups, each of the second TSV groups being adjacent to the first TSV group.

14. The TSV short test method of claim 13, wherein providing the first voltage to the first TSV group, and providing the second voltage to the at least one second TSV group comprises:
providing the first voltage to the first TSV group in each of the plurality of test groups, and providing the second voltage to the second TSV groups in the test group.

15. The TSV short test method of claim 13, wherein reading the electrical signals on the first TSV group and the at least one second TSV group sequentially comprises:
reading the electrical signals on the first TSV group and the second TSV groups in each test group.
